(19) United States
(12) Patent Application Publication
(10) Pub. No.: US 2026/0096304 A1
(43) Pub. Date: Apr. 2, 2026

(54) DISPLAY PANEL AND PREPARATION METHOD THEREOF

(71) Applicant: HKC CORPORATION LIMITED, SHENZHEN (CN)

(72) Inventors: Zhonglin CAO, SHENZHEN (CN); Lidan YE, SHENZHEN (CN)

(73) Assignee: HKC CORPORATION LIMITED, SHENZHEN (CN)

(21) Appl. No.: 19/321,243

(22) Filed: Sep. 7, 2025

(30) Foreign Application Priority Data
Sep. 30, 2024 (CN) 202411396581.5

(51) Int. Cl. H10K 59/123; H10K 59/12; H10K 59/128

(52) U.S. Cl. CPC H10K 59/123; H10K 59/1201; H10K 59/128

(57) ABSTRACT

A display panel and a preparation method thereof may be provided. The display panel may include a first display substrate, a second display substrate, and a silicon-based driving substrate. The first display substrate may include a first glass substrate and first light-emitting units. The first glass substrate may include first conductive vias. The second display substrate may include a second glass substrate and second light-emitting units. The second glass substrate may include second conductive vias. The silicon-based driving substrate may be arranged between the first glass substrate and the second glass substrate. The silicon-based driving substrate may include a plurality of third conductive vias electrically connected to the driving circuit. The third conductive vias may include third anode-electrode conductive vias and third cathode-electrode conductive vias. Two ends of each third conductive via may be electrically connected to a first light-emitting unit and a second light-emitting unit respectively.

### CROSS REFERENCE TO RELATED APPLICATIONS

This application claims priority to Chinese Patent Application No. 202411396581.5, entitled “display panel and preparation method thereof”, filed on Sep. 30, 2024, which is herein incorporated by reference in its entirety.

### TECHNICAL FIELD

The present disclosure relates to the field of display technologies, and in particular to a display panel and a preparation method thereof.

### BACKGROUND

A monocrystalline silicon driving backplane is a driving substrate formed with semiconductor devices as driving units, and the semiconductor devices are fabricated by complementary metal oxide semiconductor (CMOS) process. Compared with conventional active-matrix organic light-emitting diode (AMOLED) panels that adopt amorphous silicon, micro-crystalline silicon, or low-temperature poly-silicon thin-film transistors as backplanes, the monocrystalline silicon driving backplane may have a much higher carrier mobility. Therefore, the organic light emitting diode (OLED) display panel based on silicon is currently a type of display panel with the best performance in products of augmented reality (AR) and/or virtual reality (VR) fields.

At present, display chips that are traditionally externally bonded are integrated into a silicon-based driving backplane in silicon-based OLED display panels. A preparation method may include fabricating OLED light-emitting devices by evaporation on a silicon-based driving substrate. The specific process may include: first depositing and forming an anode electrode, then fabricating a pixel definition layer, and then depositing an organic light-emitting layer and a cathode electrode in sequence. In this way, pixel units of smaller sizes may be prepared, thereby achieving display fineness beyond a retina level, and pixel units may include many advantages such as high resolution, high integration, low power consumption, small size, and light weight or the like.

However, directly fabricating the OLED light-emitting devices by evaporation on the silicon-based driving substrate may easily affect a silicon-based driving circuit, leading to damage of the driving circuit and making it unusable, which may increase the cost.

### SUMMARY

A technical solution adopted by the present disclosure is to provide a display panel. The display panel may include: a first display substrate, a second display substrate, and a silicon-based driving substrate. The first display substrate may include a first glass substrate and a plurality of first light-emitting units. The first glass substrate may include a first surface and a second surface that are opposite to each other. The first glass substrate may include a plurality of first conductive vias extending from the first surface to the second surface. The plurality of first conductive vias may include a plurality of first anode-electrode conductive vias and a plurality of first cathode-electrode conductive vias. The plurality of first light-emitting units may be arranged on the first surface of the first glass substrate. Each of the plurality of first light-emitting units may include a first anode electrode, a first organic light-emitting layer, and a first cathode electrode that are stacked in sequence in a direction away from the first glass substrate. The first anode electrode may be electrically connected to a matched one of the plurality of first anode-electrode conductive vias. The first cathode electrode is electrically connected to one of the plurality of first cathode-electrode conductive vias. The second display substrate may include a second glass substrate and a plurality of second light-emitting units. The second glass substrate may include a third surface and a fourth surface that are opposite to each other. The second glass substrate may include a plurality of second conductive vias extending from the third surface to the fourth surface. The plurality of second conductive vias may include a plurality of second anode-electrode conductive vias and a plurality of second cathode-electrode conductive vias. The plurality of second light-emitting units may be arranged on the third surface of the second glass substrate. Each of the plurality of second light-emitting units may include a second anode electrode, a second organic light-emitting layer, and a second cathode electrode that are stacked in sequence in a direction away from the second glass substrate. The second anode electrode may be electrically connected to a matched one of the plurality of second anode-electrode conductive vias. The second cathode electrode may be electrically connected to one of the plurality of second cathode-electrode conductive vias. The silicon-based driving substrate may be stacked between the first glass substrate and the second glass substrate. The silicon-based driving substrate may include a fifth surface and a sixth surface that are opposite to each other. The fifth surface of the silicon-based driving substrate may be bonded to the second surface of the first glass substrate. The sixth surface of the silicon-based driving substrate may be bonded to the fourth surface of the second glass substrate. The silicon-based driving substrate may include a plurality of third conductive vias extending from the fifth surface to the sixth surface. Each of the plurality of third conductive vias may be electrically connected to a driving circuit of the silicon-based driving substrate. The plurality of third conductive vias may include a plurality of third anode-electrode conductive vias and a plurality of third cathode-electrode conductive vias. An end of each of the plurality of third anode-electrode conductive vias may be electrically connected to matched one of the plurality of first anode-electrode conductive vias, another end of the each of the plurality of third anode-electrode conductive vias may be electrically connected to matched one of the plurality of second anode-electrode conductive vias. An end of each of the plurality of third cathode-electrode conductive vias may be electrically connected to matched one of the plurality of first cathode-electrode conductive vias, another end of the each of the plurality of third cathode-electrode conductive vias may be electrically connected to matched one of the plurality of second cathode-electrode conductive vias.

A technical solution adopted by the present disclosure may be to provide a preparation method of a display panel. The preparation method may include: providing a first display substrate, wherein the first display substrate may include a first glass substrate and a plurality of first light-emitting units, the first glass substrate may include a first surface and a second surface that are opposite to each other, the first glass substrate may include a plurality of first conductive vias extending from the first surface to the second surface, the plurality of first conductive vias may include a plurality of first anode-electrode conductive vias and a plurality of first cathode-electrode conductive vias, the plurality of first light-emitting units may be arranged on the first surface of the first glass substrate, each of the plurality of first light-emitting units may include a first anode electrode, a first organic light-emitting layer, and a first cathode electrode that are stacked in sequence in a direction away from the first glass substrate, the first anode electrode may be electrically connected to a matched one of the plurality of first anode-electrode conductive vias, the first cathode electrode may be electrically connected to one of the plurality of first cathode-electrode conductive vias; providing a second display substrate, wherein the second display substrate may include a second glass substrate and a plurality of second light-emitting units, the second glass substrate may include a third surface and a fourth surface that are opposite to each other, the second glass substrate may include a plurality of second conductive vias extending from the third surface to the fourth surface, the plurality of second conductive vias may include a plurality of second anode-electrode conductive vias and a plurality of second cathode-electrode conductive vias, the plurality of second light-emitting units may be arranged on the third surface of the second glass substrate, each of the plurality of second light-emitting units may include a second anode electrode, a second organic light-emitting layer, and a second cathode electrode that are stacked in sequence in a direction away from the second glass substrate, the second anode electrode may be electrically connected to a matched one of the plurality of second anode-electrode conductive vias, the second cathode electrode may be electrically connected to one of the plurality of second cathode-electrode conductive vias; providing a silicon-based driving substrate, wherein the silicon-based driving substrate may include a fifth surface and a sixth surface that may be opposite to each other, the silicon-based driving substrate may include a plurality of third conductive vias extending from the fifth surface to the sixth surface, each of the plurality of third conductive vias may be electrically connected to a driving circuit of the silicon-based driving substrate, the plurality of third conductive vias include a plurality of third anode-electrode conductive vias and a plurality of third cathode-electrode conductive vias; and, bonding the fifth surface of the silicon-based driving substrate to the second surface of the first glass substrate, and bonding the sixth surface of the silicon-based driving substrate to the fourth surface of the second glass substrate, wherein an end of each third anode-electrode conductive via of the plurality of third anode-electrode conductive vias may be electrically connected to a matched first anode-electrode conductive via of the plurality of first anode-electrode conductive vias, another end of the each third anode-electrode conductive via may be electrically connected to a matched second anode-electrode conductive via of the plurality of second anode-electrode conductive vias, an end of each third cathode-electrode conductive via of the plurality of third cathode-electrode conductive vias may be electrically connected to a matched first cathode-electrode conductive via of the plurality of first cathode-electrode conductive vias, another end of the each third cathode-electrode conductive via may be electrically connected to a matched second cathode-electrode conductive via of the plurality of second cathode-electrode conductive vias.

### BRIEF DESCRIPTION OF THE DRAWINGS

FIG. 1 is a schematic structural view of a first embodiment of a display panel according to the present disclosure.

FIG. 2 is an enlarged view of a portion in a rectangular A of the display panel in FIG. 1.

FIG. 3 is a schematic exploded view of the structure shown in FIG. 2.

FIG. 4 is a schematic structural view of a second embodiment of a display panel according to the present disclosure.

FIG. 5 is an enlarged view of a portion in a rectangular B of the display panel in FIG. 4.

FIG. 6 is a schematic exploded view of the structure shown in FIG. 5.

FIG. 7 is a schematic flowchart of a third embodiment of a preparation method of a display panel according to the present disclosure.

FIG. 8 is a schematic structural view corresponding to the operation at block S1 of FIG. 7.

FIG. 9 is a schematic structural view corresponding to the operation at block S2 of FIG. 7.

FIG. 10 is a schematic structural view corresponding to the operation at block S3 of FIG. 7.

FIG. 11 is a specific schematic flowchart of the operation at block S3.

FIG. 12 is a schematic structural view corresponding to the operations at blocks S31 and S32 of FIG. 11.

FIG. 13 is a schematic structural view corresponding to the operation at block S33 of FIG. 11.

FIG. 14 is a schematic structural view corresponding to the operation at block S34 of FIG. 11.

FIG. 15 is a schematic structural view corresponding to the operation at block S35 of FIG. 11.

FIG. 16 is a schematic structural view corresponding to the operation at block S36 of FIG. 11.

FIG. 17 is a schematic structural view corresponding to the operation at block S37 of FIG. 11.

FIG. 18 is a schematic structural view corresponding to the operations at blocks S38 and S39 of FIG. 11.

FIG. 19 is a schematic flowchart of a fourth embodiment of an operation at block S3 of the preparation method of a display panel according to the present disclosure.

FIG. 20 is a schematic structural view corresponding to the operations at blocks S31A and S32A of FIG. 19.

FIG. 21 is a schematic structural view corresponding to the operation at block S33A of FIG. 19.

FIG. 22 is a schematic structural view corresponding to the operation at block S34A of FIG. 19.

FIG. 23 is a schematic structural view corresponding to the operation at block S35A of FIG. 19.

FIG. 24 is a schematic structural view corresponding to the operation at block S36A of FIG. 19.

FIG. 25 is a schematic structural view corresponding to the operation at block S37A of FIG. 19.

FIG. 26 is a schematic structural view corresponding to the operations at blocks S38A and S39A of FIG. 19.

### DETAILED DESCRIPTION

Technical solutions in embodiments of the present disclosure will be described clearly and thoroughly in connection with accompanying drawing of the embodiments of the present disclosure. Obviously, the described embodiments are only a part of the embodiments, but not all of them. All other embodiments by a person of ordinary skills in the art based on embodiments of the present disclosure without creative efforts should all be within the protection scope of the present disclosure.

The terms “first”, “second”, and “third” in this disclosure are only for the purpose of description, and cannot be construed as indicating or implying relative importance or implicitly indicating the number of technical features referred to. Therefore, the features defined with “first”, “second”, and “third” may explicitly or implicitly include at least one of the features. In the description of the present disclosure, “a plurality of” means at least two, such as two, three, etc., unless otherwise specifically defined. All directional indicators (such as up, down, left, right, front, back . . . ) in embodiments of the present disclosure are only used to explain a motion state, a relative positional relationship between the components in a specific posture (as shown in the drawings). If the specific posture changes, then the directional indication will change accordingly. In addition, the terms “include”, “comprise” and any variations thereof are intended to cover non-exclusive inclusion. For example, a process, a method, a system, a product, or a device that includes a series of operations or units is not limited to the listed operations or units, but optionally includes unlisted operations or units, or optionally also includes other operations or units inherent to these processes, methods, products or devices.

Reference to “embodiments” herein means that a specific feature, structure, or characteristic described in conjunction with the embodiments may be included in at least one embodiment of the present disclosure. The appearance of this phrase in various locations in the specification does not necessarily refer to the same embodiment, nor is it an independent or alternative embodiment mutually exclusive with other embodiments. Those skilled in the art may explicitly and implicitly understand that, the embodiments described herein may be combined with other embodiments.

The present disclosure will be described in detail below with reference to the drawings and embodiments.

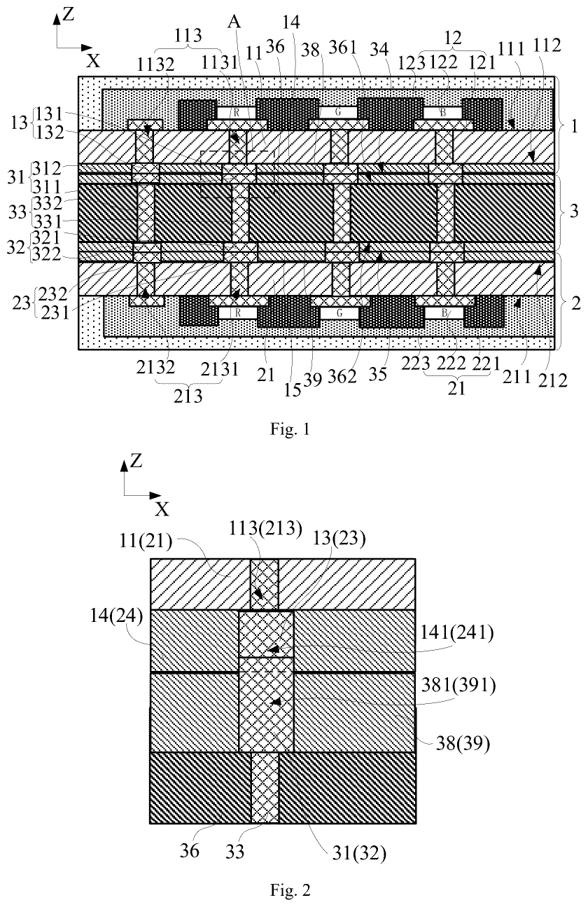

As illustrated in FIG. 1, FIG. 1 is a schematic structural view of a first embodiment of a display panel according to the present disclosure. The present disclosure provides the display panel. This display panel may be an OLED display panel. The display panel may include a first display substrate 1, a second display substrate 2, and a silicon-based driving substrate 3.

The first display substrate 1 may include a first glass substrate 11 and a plurality of first light-emitting units 12. The first glass substrate 11 may include a first surface 111 and a second surface 112 that are opposite to each other. The first glass substrate 11 may include a plurality of first conductive vias 113 that extend from the first surface 111 to the second surface 112. The plurality of first conductive vias 113 may include a plurality of first anode-electrode conductive vias 1131 and a plurality of first cathode-electrode conductive vias 1132. The plurality of first cathode-electrode conductive vias 1132 may surround the plurality of first anode-electrode conductive vias 1131.

The plurality of first light-emitting units 12 may be arranged on the first surface 111 of the first glass substrate 11. Each of the plurality of first light-emitting units 12 may include a first anode electrode 121, a first organic light-emitting layer 122, and a first cathode electrode 123 that are stacked in sequence in a direction away from the first glass substrate 11. Specifically, a pixel definition layer may also be arranged on the first surface 111 of the first glass substrate 11. The pixel definition layer may protrude from the first glass substrate 11 and enclose to form a plurality of first pixel accommodating regions (not illustrated in the drawings). The plurality of first light-emitting units 12 may be respectively arranged within the plurality of first pixel accommodation regions. The plurality of first pixel accommodating regions may be arranged in one-to-one correspondence with the plurality of first conductive vias 113. The first anode electrode 121 may be electrically connected to a matched first anode-electrode conductive via 1131, so as to transmit an anode drive signal to the first anode electrode 121 through the first anode-electrode conductive via 1131. The first cathode electrode 123 may be electrically connected to the first cathode-electrode conductive via 1132, so as to transmit a cathode drive signal to the first cathode electrode 123 through the first cathode-electrode conductive via 1132.

The first anode electrode 121 may be arranged on the surface of the first glass substrate 11 exposed through the first pixel accommodation region. The first pixel definition layer may cover an edge of the first anode electrode 121. This is to avoid a contact between the first anode electrodes 121 of adjacent first light-emitting units 12. Such a contact may cause a case of signal crosstalk. The first organic light-emitting layer 122 may be arranged on a side surface of the first anode electrode 121 away from the first glass substrate 11. The first cathode electrode 123 may be arranged on a side of the first organic light-emitting layer 122 away from the first anode electrode 121, and cover the first organic light-emitting layer 122 of the plurality of first light-emitting units 12, so as to form a full-surface of common cathode. The first anode electrode 121 may transmit the anode drive signal to the first organic light-emitting layer 122, and the first cathode electrode 123 may transmit the cathode drive signal to the first organic light-emitting layer 122, so as to drive the first organic light-emitting layer 122 to emit light.

In some embodiments, the first light-emitting unit 12 may include light-emitting units with different emission colors, such as red light-emitting units, green light-emitting units, and blue light-emitting units, so as to achieve colorful display. Specifically, the emission color of the first light-emitting unit 12 may be determined by the emission color of the organic light-emitting layer. Alternatively, in some other embodiments, the first light-emitting units 12 may also be light-emitting units of a same color, such as white, red, green, blue, or other colors, which may be specifically set according to actual needs. For example, the first light-emitting unit 12 may be white, gray-scale display may be achieved by controlling a brightness of the first light-emitting unit 12. A color resistant layer may also be additionally arranged above the first light-emitting unit 12 to achieve colorful display. For example, if the first light-emitting units 12 are blue, a red quantum dot layer may be additionally arranged above some of the first light-emitting units 12, and a green quantum dot layer may be additionally arranged above some of the first light-emitting units 12, so as to achieve colorful display.

The second display substrate 2 may include a second glass substrate 21 and a plurality of second light-emitting units 22. The second glass substrate 21 may include a third surface 211 and a fourth surface 212 that are opposite to each other. The second glass substrate 21 may include a plurality of second conductive vias 213 that extend from third surface 211 to the fourth surface 212. The plurality of second conductive vias 213 may include a plurality of second anode-electrode conductive vias 2131 and a plurality of second cathode-electrode conductive vias 2132. The plurality of second cathode-electrode conductive vias 2132 may surround the plurality of second anode-electrode conductive vias 2131.

The plurality of second light-emitting units 22 may be arranged on the third surface 211 of the second glass substrate 21. Each of the plurality of second light-emitting units 22 may include a second anode electrode 221, a second organic light-emitting layer 222, and a second cathode electrode 223 that are stacked in sequence in a direction away from the second glass substrate 21. Specifically, a pixel definition layer may also be arranged on the third surface 211 of the second glass substrate 21. The pixel definition layer may protrude from the second glass substrate 21 and enclose to form a plurality of second pixel accommodating regions (not illustrated in the drawings). The plurality of second light-emitting units 22 may be respectively arranged within the plurality of second pixel accommodation regions. The plurality of second pixel accommodating regions may be arranged in one-to-one correspondence with the plurality of second conductive vias 213. The second anode electrode 221 may be electrically connected to a matched second anode-electrode conductive via 2131, so as to transmit the anode drive signal to the second anode electrode 221 through the second anode-electrode conductive via 2131. The second cathode electrode 223 may be electrically connected to the second cathode-electrode conductive via 2132, so as to transmit the cathode drive signal to the second cathode electrode 223 through the second cathode-electrode conductive via 2132.

The specific structure and function of the second light-emitting unit 22 are the same as or similar to those of the first light-emitting unit 12. For details, reference may be made to the above-described first light-emitting unit 12, which will not be repeated here.

The silicon-based driving substrate 3 may be stacked and arranged between the first glass substrate 11 and the second glass substrate 21. The silicon-based driving substrate 3 may be bonded to the first glass substrate 11, so as to transmit the drive signal to the first light-emitting unit 12. The silicon-based driving substrate 3 may be bonded to the second glass substrate 21, so as to transmit the drive signal to the second light-emitting unit 22. Specifically, the silicon-based driving substrate 3 may include a fifth surface 34 and a sixth surface 35 that are opposite to each other. The fifth surface 34 of the silicon-based driving substrate 3 may be bonded to the second surface 112 of the first glass substrate 11. The sixth surface 35 of the silicon-based driving substrate 3 may be bonded to the fourth surface 212 of the second glass substrate 21.

By providing the first light-emitting unit 12 on the first glass substrate 11 and by defining the first conductive via 113 extending through the first glass substrate 11, the silicon-based driving substrate 3 may be in contact and electrically connected to the first anode electrode 121 of the matched first light-emitting unit 12 through the first conductive via 113. Meanwhile, by providing the second light-emitting unit 22 on the second glass substrate 21 and by defining the second conductive via 213 extending through the second glass substrate 21, the silicon-based driving substrate 3 may be in contact and electrically connected to the second anode electrode 221 of the matched second light-emitting unit 22 through the second conductive via 213. Thus, an electrical coupling between the first light-emitting unit 12 and the silicon-based driving substrate 3, and an electrical coupling between the second light-emitting unit 22 and the silicon-based driving substrate 3 may both be achieved, thereby enabling the silicon-based driving substrate 3 to drive the first light-emitting unit 12 and the second light-emitting unit 22. In this way, the first light-emitting units 12 may be fabricated on the first glass substrate 11, the second light-emitting units 22 may be fabricated on the second glass substrate 21, and then a process of bonding to the silicon-based driving substrate 3 may be performed. There is no need to directly fabricate the light-emitting units on the silicon-based driving substrate 3, the problem of reduced product yield caused by damage to the pixel driving circuit due to directly fabrication of the light-emitting units on the silicon-based driving substrate 3 may be avoided.

The silicon-based driving substrate 3 may include a plurality of third conductive vias 33 extending from the fifth surface 34 to the sixth surface 35. The third conductive vias 33 may be electrically connected to a driving circuit of the silicon-based driving substrate 3. The driving circuit may transmit the drive signal through the third conductive vias 33. The plurality of third conductive vias 33 may include a plurality of third anode-electrode conductive vias 331 and a plurality of third cathode-electrode conductive vias 332.

An end of each third anode-electrode conductive via 331 may be electrically connected to the matched first anode-electrode conductive via 1131, another end of the each third anode-electrode conductive via 331 may be electrically connected to a matched second anode-electrode conductive via 2131. Thus, the driving circuit may transmit the anode drive signal to the first light-emitting unit 12 through the matched first anode-electrode conductive via 1131, and transmit the anode drive signal to the second light-emitting unit 22 through a matched second anode-electrode conductive via 2131. An end of each third cathode-electrode conductive via 332 may be electrically connected to the matched first cathode-electrode conductive via 1132, another end of the each third cathode-electrode conductive via 332 may be electrically connected to a matched second cathode-electrode conductive via 2132. Thus, the driving circuit may transmit the cathode drive signal to the first light-emitting unit 12 through the matched first cathode-electrode conductive via 1132, and transmit the cathode drive signal to the second light-emitting unit 22 through a matched second cathode-electrode conductive via 2132.

By arranging the third conductive vias 33 penetrating through the silicon-based driving substrate 3 and arranging the first display substrate 1 and the second display substrate 2 on the two opposite surfaces of the silicon-based driving substrate 3 respectively, both the first display substrate 1 and the second display substrate 2 may be enabled to electrically connect with the driving circuit through the third conductive vias 33. The driving circuit may synchronously transmit drive signals to the first display substrate 1 and the second display substrate 2 through the third conductive vias 33, thereby achieving double-sided synchronous display of the display panel, effectively reducing manufacturing costs, and facilitating lighting and thinning of the display panel.

As further illustrated in FIG. 1, in some embodiments, the first display substrate 1 may further include a plurality of first bonding portions 13. The plurality of first bonding portions 13 may be arranged on the second surface 112 of the first glass substrate 11. The plurality of first bonding portions 13 may specifically include a plurality of first anode-electrode bonding portions 131 and a plurality of first cathode-electrode bonding portions 132.

Each first anode-electrode bonding portion 131 may be at least partially arranged within a matched first anode-electrode conductive via 1131. The first anode-electrode bonding portion 131 may be electrically connected to the matched first anode electrode 121 through the matched first anode-electrode conductive via 1131, so as to transmit the anode drive signal to the first anode electrode 121 of the matched first light-emitting unit 12 through the first anode-electrode conductive via 1131. Each first cathode-electrode bonding portion 132 may be at least partially arranged within the matched first cathode-electrode conductive via 1132. The first cathode-electrode bonding portion 132 may be electrically connected to the first cathode electrode 123 through the matched first cathode-electrode conductive via 1132, so as to transmit the cathode drive signal to the first cathode electrode 123 of the matched first light-emitting unit 12 through the first cathode-electrode conductive via 1132.

The second display substrate 2 may further include a plurality of second bonding portions 23. The plurality of second bonding portions 23 may be arranged on the fourth surface 212 of the second glass substrate 21. The plurality of second bonding portions 23 may specifically include a plurality of second anode-electrode bonding portions 231 and a plurality of second cathode-electrode bonding portions.

Each second anode-electrode bonding portion 231 may be at least partially arranged within a matched second anode-electrode conductive via 2131. The second anode-electrode bonding portion 231 may be electrically connected to the matched second anode electrode 221 through the matched second anode-electrode conductive via 2131, so as to transmit the anode drive signal to the second anode electrode 221 of the matched second light-emitting unit 22 through the second anode-electrode conductive via 2131. Each second cathode-electrode bonding portion may be at least partially arranged within the matched second cathode-electrode conductive via 2132. The second cathode-electrode bonding portion may be electrically connected to the second cathode electrode 223 through the matched second cathode-electrode conductive via 2132, so as to transmit the cathode drive signal to the second cathode electrode 223 of the matched second light-emitting unit 22 through the second cathode-electrode conductive via 2132.

As illustrated in FIG. 1, The silicon-based driving substrate 3 may further include a plurality of first bonding electrodes 31 and a plurality of second bonding electrodes 32. The plurality of first bonding electrodes 31 may include first anode-electrode bonding electrodes 311 and a plurality of first cathode-electrode bonding electrodes 312. The plurality of first anode-electrode bonding electrodes 311 may be arranged on the fifth surface 34 of the silicon-based driving substrate 3. The plurality of first anode-electrode bonding electrodes 311 may be aligned and bonded with the plurality of first anode-electrode bonding portions 131 in one-to-one correspondence. The silicon-based driving substrate 3 may be able to transmit the anode drive signal to the first anode electrode 121 through the first anode-electrode bonding electrode 311 and the first anode-electrode bonding portion 131. The plurality of first cathode-electrode bonding electrodes 312 may be arranged on the fifth surface 34 of the silicon-based driving substrate 3. The plurality of first cathode-electrode bonding electrodes 312 may be aligned and bonded with the plurality of first cathode-electrode bonding portions 132 in one-to-one correspondence. The silicon-based driving substrate 3 may be able to transmit the cathode drive signal to the first cathode electrode 123 through the first cathode-electrode bonding electrode 312 and the first cathode-electrode bonding portion 132.

The plurality of second bonding electrodes 32 may include second anode-electrode bonding electrodes 321 and a plurality of second cathode-electrode bonding electrodes 322. The plurality of second anode-electrode bonding electrodes 321 may be arranged on the sixth surface 35 of the silicon-based driving substrate 3. The plurality of second anode-electrode bonding electrodes 321 may be aligned and bonded with the plurality of second anode-electrode bonding portions 231 in one-to-one correspondence. The silicon-based driving substrate 3 may be able to transmit the anode drive signal to the first anode electrode 121 through the second anode-electrode bonding electrode 321 and the second anode-electrode bonding portion 231. Each second anode-electrode bonding electrode 321 may be electrically connected to the matched first anode-electrode bonding electrode 311 through the matched third anode-electrode conductive via 331, The silicon-based driving substrate 3 may be able to synchronously transmit the anode drive signals to the matched first anode-electrode bonding electrode 311 and the matched second anode-electrode bonding electrode 321 through the third anode-electrode conductive via 331.

The plurality of second cathode-electrode bonding electrodes 322 may be arranged on the sixth surface 35 of the silicon-based driving substrate 3. The plurality of second cathode-electrode bonding electrodes 322 may be aligned and bonded with the plurality of second cathode-electrode bonding portions in one-to-one correspondence. The silicon-based driving substrate 3 may be able to transmit the cathode drive signal to the first cathode electrode 123 through the second cathode-electrode bonding electrode 322 and the second cathode-electrode bonding portion. Each second cathode-electrode bonding electrode 322 may be electrically connected to the matched first cathode-electrode bonding electrode 312 through the matched third cathode-electrode conductive via 332, The silicon-based driving substrate 3 may be able to synchronously transmit the cathode drive signals to the matched first cathode-electrode bonding electrode 312 and the matched second cathode-electrode bonding electrode 322 through the third cathode-electrode conductive via 332.

As further illustrated in FIG. 1, in some embodiments, the first display substrate 1 may further include a first insulating layer 14 arranged on the second surface 112 of the first glass substrate 11. The first insulating layer 14 may be configured to protect the first anode-electrode bonding portion 131 and the first cathode-electrode bonding portion 132, thereby avoiding bonding failure caused by external water and oxygen invading and corroding metals. The first insulating layer 14 may define a first through-hole 141 at a location matching with the first conductive via 113. The first through-hole 141 may extend through the first insulating layer 14 along a stacking direction Z. The first bonding portion 13 may be embedded in the first through-hole 141. Specifically, a portion of the first bonding portion 13 close to the first light-emitting unit 12 may be embedded in the first conductive via 113 and contact the first light-emitting unit 12. A portion of the first bonding portion 13 close to the first bonding electrode 31 may be embedded in the first through-hole 141 and contact the first bonding electrode 31. In this way, the first bonding electrode 31 and the first light-emitting unit 12 may be electrically connect to each other.

The second display substrate 2 may further include a second insulating layer 24 arranged on the fourth surface 212 of the second glass substrate 21. The second insulating layer 24 may be configured to protect the second anode-electrode bonding portion 231 and the second cathode-electrode bonding portion, thereby avoiding bonding failure caused by external water and oxygen invading and corroding metals. The second insulating layer 24 may define a second through-hole 241 at a location matching with the second conductive via 213. The second through-hole 241 may extend through the second insulating layer 24 along the stacking direction Z. The second bonding portion 23 may be embedded in the second through-hole 241. Specifically, a portion of the second bonding portion 23 close to the second light-emitting unit 22 may be embedded in the second conductive via 213 and contact the second light-emitting unit 22. A portion of the second bonding portion 23 close to the second bonding electrode 32 may be embedded in the second through-hole 241 and contact the second bonding electrode 32. In this way, the second bonding electrode 32 and the second light-emitting unit 22 may be electrically connect to each other.

The silicon-based driving substrate 3 may further include a silicon base substrate 36, a driving circuit layer 37, a first protective layer 38 and a second protective layer 39 arranged in a stacked manner. The silicon base substrate 36 may include a seventh surface 361 and an eighth surface 362 that are opposite to each other. The driving circuit layer 37 may be arranged on the seventh surface 361 of the silicon base substrate 36. The silicon base substrate 36 may refer to a base plate based on monocrystalline silicon material. Specifically, the driving circuit layer 37 may include a driving circuit electrically connected to the plurality of first bonding electrodes 31, and is configured to transmit the drive signal to the first light-emitting unit 12 through the first bonding portion 13, and transmit the drive signal to the second light-emitting unit 22 through the second bonding portions 23. The driving circuit may include an active driving circuit integrated on a monocrystalline silicon base substrate through a complementary metal-oxide-semiconductor (CMOS) process. The driving circuit may include a plurality of “3T1C” (3 thin-film transistors and 1 capacitor) structure, so as to achieve independent control of each first light-emitting unit 12 and each second light-emitting unit 22 and a high-quality image display.

The silicon-based driving substrate 3 may further include a display control circuit (not illustrated in the drawings) electrically connected to the driving circuit. The display control circuit may control the first light-emitting units 12 and the second light-emitting units 22 to display through the driving circuit. The display control circuit may be an integrated circuit (IC) integrated on the silicon-based driving substrate 3.

A first protective layer 38 covering the driving circuit layer 37 may be further arranged on a side of the silicon-based driving substrate 3 close to the first glass substrate 11. The first protective layer 38 may be configured to protect the first bonding electrodes 31 and the driving circuit, avoiding a case in which external water and oxygen invade and corrode the driving circuit and the first bonding electrodes 31. A third through-hole 381 may be defined at a location of the first protective layer 38 matching with the third conductive via 33. The first bonding electrode 31 may be partially embedded in the third through-hole 381 and electrically connected to the driving circuit.

A second protective layer 39 may be arranged on the eighth surface 362 of the silicon base substrate 36. The second protective layer 39 may be configured to protect the second bonding electrodes 32, avoiding a case in which external water and oxygen invade and corrode the second bonding electrode 32. A fourth through-hole 391 may be defined at a location of the second protective layer 39 matching with the third conductive via 33. The second bonding electrode 32 may be partially embedded in the fourth through-hole 391 and electrically connected to the driving circuit through the third conductive via 33. Materials of the first protective layer 38 and the second protective layer 39 may be inorganic insulating materials such as silicon dioxide, silicon nitride, or silicon oxynitride, or the like.

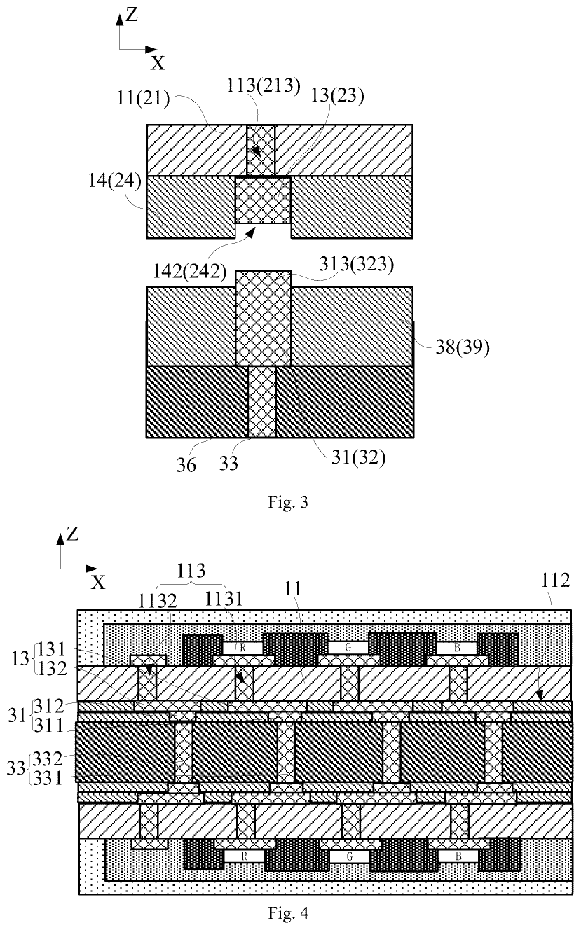

As illustrated in FIG. 2 and FIG. 3, FIG. 2 is an enlarged view of a portion in a rectangular A of the display panel in FIG. 1, FIG. 3 is a schematic exploded view of the structure shown in FIG. 2. Further, a surface of the first bonding portion 13 away from the first glass substrate 11 may be lower than a surface of the first insulating layer 14 away from the first glass substrate 11, such that the first bonding portion 13 and the first through-hole 141 may form a first groove portion 142. One end of the first bonding electrode 31 away from the silicon base substrate 36 may protrude beyond a surface of the first protective layer 38 away from the silicon base substrate 36, such that a portion of the first bonding electrode 31 may protrude beyond the first protective layer 38 to form a first protruding portion 313. Thus, when the first bonding electrode 31 is bonded to the first bonding portion 13, the first protruding portion 313 may be embedded within the first groove portion 142 to achieve precise alignment. This may provide a guiding effect during alignment, further improving alignment accuracy. Additionally, a location of the first bonding electrode 31 may be limited, further preventing issues such as displacement after the alignment process.

A surface of the second bonding portion 23 away from the second glass substrate 21 may be lower than a surface of the second insulating layer 24 away from the second glass substrate 21, such that the second bonding portion 23 and the second through-hole 241 may form a second groove portion 242. One end of the second bonding electrode 32 away from the silicon base substrate 36 may protrude beyond a surface of the second protective layer 39 away from the silicon base substrate 36, such that a portion of the second bonding electrode 32 may protrude beyond the second protective layer 39 to form a second protruding portion 323. Thus, when the second bonding electrode 32 is bonded to the second bonding portion 23, the second protruding portion 323 may be embedded within the second groove portion 242 to achieve precise alignment. The alignment accuracy may be further increased. Additionally, a location of the second bonding electrode 32 may be limited, further preventing issues such as displacement after the alignment process.

As illustrated in FIG. 1, in a specific embodiment, the matched first conductive via 113, third conductive via 33, and second conductive via 213 may be coaxially arranged to reduce processing difficulty, improve alignment accuracy, simplify the manufacturing process, and reduce manufacturing costs. It should be noted that, the matched first conductive via 113, third conductive via 33, and second conductive via 213 mean that, a first conductive via 113 is electrically connected to a second conductive via 213 through a third conductive via 33, so that the driving circuit may synchronously transmit the drive signals to the first conductive via 113 and the second conductive via 213 through the third conductive via 33, thereby achieving the double-sided synchronous display.

Specifically, the matched first anode-electrode conductive via 1131, third anode-electrode conductive via 331, and second anode-electrode conductive via 2131 may be coaxially arranged, so that the driving circuit may synchronously transmit the anode drive signals to the matched first anode-electrode conductive via 1131 and the matched second anode-electrode conductive via 2131 through the third anode-electrode conductive via 331. The matched first cathode-electrode conductive via 1132, third cathode-electrode conductive via 332, and second cathode-electrode conductive via 2132 may be coaxially arranged, so that the driving circuit may synchronously transmit the cathode drive signals to the matched first cathode-electrode conductive via 1132 and the matched second cathode-electrode conductive via 2132 through the third cathode-electrode conductive via 332.

The first bonding electrode 31 and the first bonding portion 13 that are bonded to each other may be arranged between the first conductive via 113 and the third conductive via 33, so that the driving circuit may transmit the drive signals to the first conductive via 113 through the first bonding electrode 31 and the first bonding portion 13. The first bonding electrode 31 and the first bonding portion 13 may also be coaxially arranged with the third conductive via 33.

The second bonding electrode 32 and the second bonding portion 23 that are bonded to each other may be arranged between the second conductive via 213 and the third conductive via 33, so that the driving circuit may transmit the drive signals to the second conductive via 213 through the second bonding electrode 32 and the second bonding portion 23. The second bonding electrode 32 and the second bonding portion 23 may also be coaxially arranged with the third conductive via 33. In other words, the matched first conductive via 113, first bonding portion 13, first bonding electrode 31, third conductive via 33, second bonding electrode 32, second bonding portion 23, and second conductive via 213 may all be coaxially arranged. In this way, the processing difficulty may be reduced, the alignment accuracy may be increased, the manufacturing process may be simplified, and the manufacturing costs may be reduced.

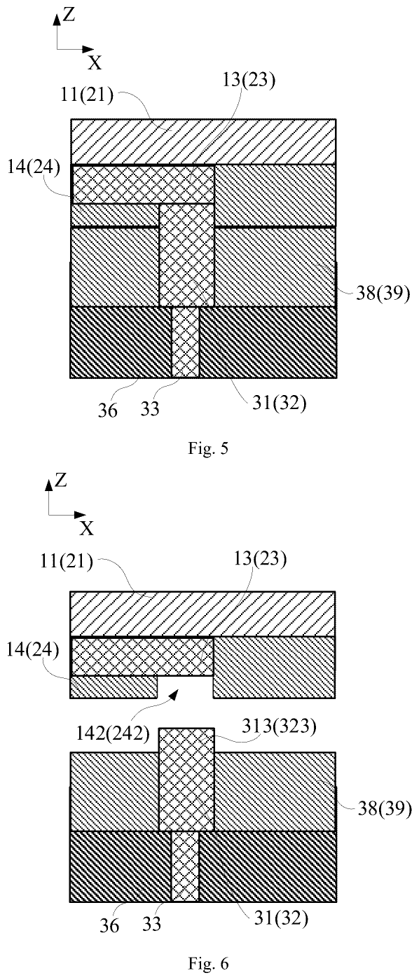

As illustrated in FIG. 4 and FIG. 6, FIG. 4 is a schematic structural view of a second embodiment of a display panel according to the present disclosure. FIG. 5 is an enlarged view of a portion in a rectangular B of the display panel in FIG. 4. FIG. 6 is a schematic exploded view of the structure shown in FIG. 5. The structure of the display panel provided in the second embodiment of the present disclosure is basically the same as the structure of the display panel provided in the first embodiment of the present disclosure. The difference may lie in the following that: in the second embodiment of the present disclosure, the matched first conductive via 113 and third conductive via 33 are arranged in a misaligned manner. Thus, when the first display substrate 1 is aligned and bonded to the silicon-based driving substrate 3, the pressure exerted by the first protruding portion 313 of the first bonding electrode 31 onto the first bonding portion 13 may be transferred to the first glass substrate 11 by the portion of the first bonding portion 13 located on the second surface 112, In this way, a case may be prevented, in which case the first protruding portion 313 directly squeezes the portion of the first bonding portion 13 located within the first conductive via 113 and the first bonding portion 13 is caused to fall off from the first conductive via 113. Similarly, the matched second conductive via 213 and third conductive via 33 are arranged in a misaligned manner. In this way, a case may be prevented, in which case the second protruding portion 323 directly squeezes the portion of the second bonding portion 23 located within the second conductive via 213 and the second bonding portion 23 is caused to fall off from the second conductive via 213.

As illustrated in FIG. 4, FIG. 5, and FIG. 6, the first bonding electrode 31 and the first bonding portion 13 that are bonded to each other are arranged between the first glass substrate 11 and the third conductive via 33. Specifically, a portion of the first bonding portion 13 may be arranged within the first conductive via 113, and another portion of the first bonding portion 13 may be arranged outside the first conductive via 113. The portion of the first bonding portion 13 arranged outside the first conductive via 113 may extend from the first conductive via 113 along a first direction X and cover a portion of the second surface 112. The first direction X may be perpendicular to the stacking direction Z. The first protruding portion 313 of the first bonding electrode 31 may be bonded to the portion of the first bonding portion 13 covering the second surface 112.

The second bonding electrode 32 and the second bonding portion 23 that are bonded to each other may be arranged between the second glass substrate 21 and the third conductive via 33. Specifically, a portion of the second bonding portion 23 may be arranged within the second conductive via 213, and another portion of the second bonding portion 23 may be arranged outside the second conductive via 213. The portion of the second bonding portion 23 arranged outside the second conductive via 213 may extend from the second conductive via 213 along a first direction X and cover a portion of the fourth surface 212. The second protruding portion 323 of the second bonding electrode 32 may be bonded to the portion of the second bonding portion 23 covering the fourth surface 212.

As illustrated in FIG. 4, preferably, the matched first conductive via 113 and second conductive via 213 may further be arranged in a coaxial manner. In this way, the processing difficulty may be reduced, the alignment accuracy may be increased, the manufacturing process may be simplified, and the manufacturing costs may be reduced.

The present disclosure provides the display panel. The display panel may include the first display substrate 1, the second display substrate 2, and the silicon-based driving substrate 3. The first display substrate 1 may include the first glass substrate 11 and the plurality of first light-emitting units 12. The second display substrate 2 may include the second glass substrate 21 and the plurality of second light-emitting units 22. The silicon-based driving substrate 3 may be stacked between the first glass substrate 11 and the second glass substrate 21. By arranging the third conductive vias 33 penetrating through the silicon-based driving substrate 3 and arranging the first display substrate 1 and the second display substrate 2 on the two opposite surfaces of the silicon-based driving substrate 3 respectively, both the first display substrate 1 and the second display substrate 2 may be enabled to electrically connect with the driving circuit through the third conductive vias 33. The driving circuit may synchronously transmit drive signals to the first display substrate 1 and the second display substrate 2 through the third conductive vias 33, thereby achieving double-sided synchronous display of the display panel, effectively reducing manufacturing costs, and facilitating lighting and thinning of the display panel. By providing the first light-emitting unit 12 on the first glass substrate 11 and by defining the first conductive via 113 extending through the first glass substrate 11, the silicon-based driving substrate 3 may be in contact and electrically connected to the first anode electrode 121 of the matched first light-emitting unit 12 through the first conductive via 113. Meanwhile, by providing the second light-emitting unit 22 on the second glass substrate 21 and by defining the second conductive via 213 extending through the second glass substrate 21, the silicon-based driving substrate 3 may be in contact and electrically connected to the second anode electrode 221 of the matched second light-emitting unit 22 through the second conductive via 213. Thus, an electrical coupling between the first light-emitting unit 12 and the silicon-based driving substrate 3, and an electrical coupling between the second light-emitting unit 22 and the silicon-based driving substrate 3 may both be achieved, thereby enabling the silicon-based driving substrate 3 to drive the first light-emitting unit 12 and the second light-emitting unit 22. In this way, the first light-emitting units 12 may be fabricated on the first glass substrate 11, the second light-emitting units 22 may be fabricated on the second glass substrate 21, and then a process of bonding to the silicon-based driving substrate 3 may be performed. There is no need to directly fabricate the light-emitting units on the silicon-based driving substrate 3, the problem of reduced product yield caused by damage to the pixel driving circuit due to directly fabrication of the light-emitting units on the silicon-based driving substrate 3 may be avoided.

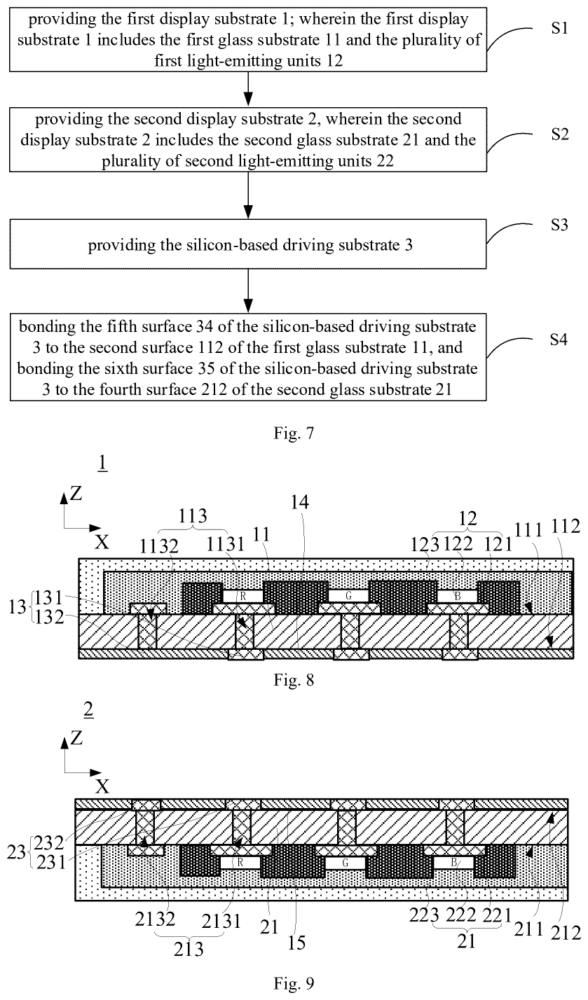

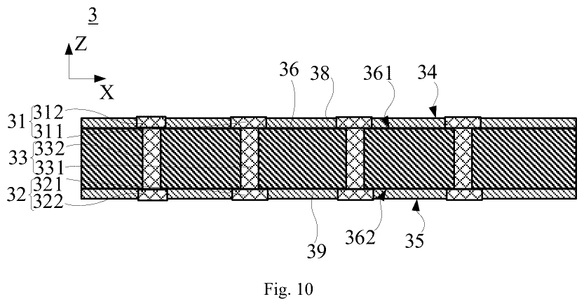

As illustrated in FIG. 7 to FIG. 10, FIG. 7 is a schematic flowchart of a third embodiment of a preparation method of a display panel according to the present disclosure. FIG. 8 is a schematic structural view corresponding to the operation at block S1 of FIG. 7. FIG. 9 is a schematic structural view corresponding to the operation at block S2 of FIG. 7. FIG. 10 is a schematic structural view corresponding to the operation at block S3 of FIG. 7. A preparation method of the display panel may be provided in the present disclosure. The preparation method may be configured to prepare the display panel referred to in any of the above-mentioned embodiments. The preparation method may include specific operations at blocks illustrated in FIG. 7.

The operation at block S1: providing a first display substrate 1; wherein the first display substrate 1 may include the first glass substrate 11 and the plurality of first light-emitting units 12.

In some embodiments, as illustrated in FIG. 8, the first glass substrate 11 may include the first surface 111 and the second surface 112 that are opposite to each other. The first glass substrate 11 may include the plurality of first conductive vias 113 that extend from the first surface 111 to the second surface 112. The plurality of first conductive vias 113 may include the plurality of first anode-electrode conductive vias 1131 and the plurality of first cathode-electrode conductive vias 1132. The plurality of first cathode-electrode conductive vias 1132 may surround the plurality of first anode-electrode conductive vias 1131.

The plurality of first light-emitting units 12 may be arranged on the first surface 111 of the first glass substrate 11. Each of the plurality of first light-emitting units 12 may include the first anode electrode 121, the first organic light-emitting layer 122, and the first cathode electrode 123 that are stacked in sequence in a direction away from the first glass substrate 11. Specifically, the pixel definition layer may also be arranged on the first surface 111 of the first glass substrate 11. The pixel definition layer may protrude from the first glass substrate 11 and enclose to form the plurality of first pixel accommodating regions. The plurality of first light-emitting units 12 may be respectively arranged within the plurality of first pixel accommodation regions. The plurality of first pixel accommodating regions may be arranged in one-to-one correspondence with the plurality of first conductive vias 113. The first anode electrode 121 may be electrically connected to a matched first anode-electrode conductive via 1131, so as to transmit the anode drive signal to the first anode electrode 121 through the first anode-electrode conductive via 1131. The first cathode electrode 123 may be electrically connected to the first cathode-electrode conductive via 1132, so as to transmit a cathode drive signal to the first cathode electrode 123 through the first cathode-electrode conductive via 1132.

In some embodiments, the operation at block S1 may further specifically include the following operations.

The operation at block S11: forming the plurality of first bonding portions 13 on the second surface 112 of the first glass substrate 11, wherein the plurality of first bonding portions 13 may include the plurality of first anode-electrode bonding portions 131 and the plurality of first cathode-electrode bonding portions 132. The first bonding portion 13 may be electrically connected to the matched first conductive via 113.

In some embodiments, as illustrated in FIG. 8, the plurality of first bonding portions 13 may be arranged in a one-to-one correspondence with the plurality of first conductive vias 113. The plurality of first anode-electrode bonding portions 131 may be arranged in a one-to-one correspondence with the plurality of first anode-electrode conductive vias 1131. Each of the plurality of first anode-electrode bonding portions 131 may be electrically connected to the matched first anode electrode 121 through the matched first anode-electrode conductive via 1131. The first anode electrode 121 may be configured to transmit the anode drive signal to the first organic light-emitting layer 122, so as to drive the first organic light-emitting layer 122 to emit light. The first anode-electrode bonding portion 131 may be configured for subsequent alignment and bonding with the first anode-electrode bonding electrode 311 of the silicon-based driving substrate 3, so that the anode drive signal can be transmitted to the first anode electrode 121 through the first anode-electrode bonding portion 131.

The plurality of first cathode-electrode bonding portions 132 may be arranged in a one-to-one correspondence with the plurality of first cathode-electrode conductive vias 1132. Each first cathode-electrode bonding portion 132 may be electrically connected to the matched first cathode electrode 123 through the matched first cathode-electrode conductive via 1132. The first cathode electrode 123 may be configured to transmit the cathode drive signal to the first organic light-emitting layer 122, so as to drive the first organic light-emitting layer 122 to emit light. The first cathode-electrode bonding portion 132 may be configured for subsequent alignment and bonding with the first cathode-electrode bonding electrode 312 of the silicon-based driving substrate 3, so that the cathode drive signal can be transmitted to the first cathode electrode 123 through the first cathode-electrode bonding portion 132.

The operation at block S2: providing the second display substrate 2, wherein the second display substrate 2 may include the second glass substrate 21 and the plurality of second light-emitting units 22.

In some embodiments, as illustrated in FIG. 9, the second glass substrate 21 may include the third surface 211 and the fourth surface 212 that are opposite to each other. The second glass substrate 21 may include the plurality of second conductive vias 213 that extend from third surface 211 to the fourth surface 212. The plurality of second conductive vias 213 may include the plurality of second anode-electrode conductive vias 2131 and the plurality of second cathode-electrode conductive vias 2132. The plurality of second cathode-electrode conductive vias 2132 may surround the plurality of second anode-electrode conductive vias 2131.

The plurality of second light-emitting units 22 may be arranged on the third surface 211 of the second glass substrate 21. Each of the plurality of second light-emitting units 22 may include the second anode electrode 221, the second organic light-emitting layer 222, and the second cathode electrode 223 that are stacked in sequence in the direction away from the second glass substrate 21. The second anode electrode 221 may be electrically connected to the matched second anode-electrode conductive via 2131, so as to transmit the anode drive signal to the second anode electrode 221 through the second anode-electrode conductive via 2131. The second cathode electrode 223 may be electrically connected to the second cathode-electrode conductive via 2132, so as to transmit the cathode drive signal to the second cathode electrode 223 through the second cathode-electrode conductive via 2132.

In some embodiments, the operation at block S2 may further specifically include the following operations.

Operation S21: forming the plurality of second bonding portions 23 on the fourth surface 212 of the second glass substrate 21, wherein the plurality of second bonding portions 23 may include the plurality of second anode-electrode bonding portions 231 and the plurality of second cathode-electrode bonding portions. The second bonding portion 23 may be electrically connected to the matched second conductive via 213.

In some embodiments, as illustrated in FIG. 9, the plurality of second bonding portions 23 may be arranged in a one-to-one correspondence with the plurality of second conductive vias 213. The plurality of second anode-electrode bonding portions 231 may be arranged in a one-to-one correspondence with the plurality of second anode-electrode conductive vias 2131. Each second anode-electrode bonding portion 231 may be electrically connected to the matched second anode electrode 221 through the matched second anode-electrode conductive via 2131. The second anode electrode 221 may be configured to transmit the anode drive signal to the second organic light-emitting layer 222, so as to drive the second organic light-emitting layer 222 to emit light. The second anode-electrode bonding portion 231 may be configured for subsequent alignment and bonding with the second anode-electrode bonding electrode 321 of the silicon-based driving substrate 3, so that the anode drive signal can be transmitted to the second anode electrode 221 through the second anode-electrode bonding portion 231.

The plurality of second cathode-electrode bonding portions may be arranged in a one-to-one correspondence with the plurality of second cathode-electrode conductive vias 2132. Each second cathode-electrode bonding portion may be electrically connected to the matched second cathode electrode 223 through the matched second cathode-electrode conductive via 2132. The second cathode electrode 223 may be configured to transmit the cathode drive signal to the second organic light-emitting layer 222, so as to drive the second organic light-emitting layer 222 to emit light. The second cathode-electrode bonding portion may be configured for subsequent alignment and bonding with the second cathode-electrode bonding electrode 322 of the silicon-based driving substrate 3, so that the cathode drive signal can be transmitted to the second cathode electrode 223 through the second cathode-electrode bonding portion.

The operation at block S3: providing the silicon-based driving substrate 3.

In some embodiments, as illustrated in FIG. 10, the silicon-based driving substrate 3 may include the fifth surface 34 and the sixth surface 35 that are opposite to each other. The silicon-based driving substrate 3 may include the plurality of third conductive vias 33 extending from the fifth surface 34 to the sixth surface 35. The third conductive vias 33 may be electrically connected to the driving circuit of the silicon-based driving substrate 3. The driving circuit may transmit the drive signal through the third conductive vias 33. Specifically, the plurality of third conductive vias 33 may include a plurality of third anode-electrode conductive vias 331 and a plurality of third cathode-electrode conductive vias 332. The plurality of third cathode-electrode conductive vias 332 may surround the plurality of third anode-electrode conductive vias 331. The driving circuit may be able to transmit the anode drive signal through the third anode-electrode conductive via 331, and transmit the cathode drive signal through the third cathode-electrode conductive via 332.

In some embodiments, as illustrated in FIG. 10, the plurality of first bonding electrodes 31 may be formed on the fifth surface 34 of the silicon-based driving substrate 3. The plurality of second bonding electrodes 32 may be formed on the sixth surface 35 of the silicon-based driving substrate 3. Both the first bonding electrode 31 and the second bonding electrode 32 may be electrically connected to the matched third conductive via 33. The plurality of first bonding electrodes 31 may include the plurality of first anode-electrode bonding electrodes 311 and the plurality of first cathode-electrode bonding electrodes 312. The plurality of second bonding electrodes 32 may include the plurality of second anode-electrode bonding electrodes 321 and a plurality of second cathode-electrode bonding electrodes 322. Specifically, both the first anode-electrode bonding electrode 311 and the second anode-electrode bonding electrode 321 may be electrically connected to the matched third anode-electrode conductive via 331. In this way, the driving circuit may synchronously transmit the anode drive signal to the first anode-electrode bonding electrodes 311 and the second anode-electrode bonding electrodes 321 through the third anode-electrode conductive vias 331. In addition, both the first cathode-electrode bonding electrode 312 and the second cathode-electrode bonding electrode 322 may be electrically connected to the matched third cathode-electrode conductive via 332. In this way, the driving circuit may synchronously transmit the cathode drive signal to the first cathode-electrode bonding electrode 312 and the second cathode-electrode bonding electrode 322 through the third cathode-electrode conductive via 332.

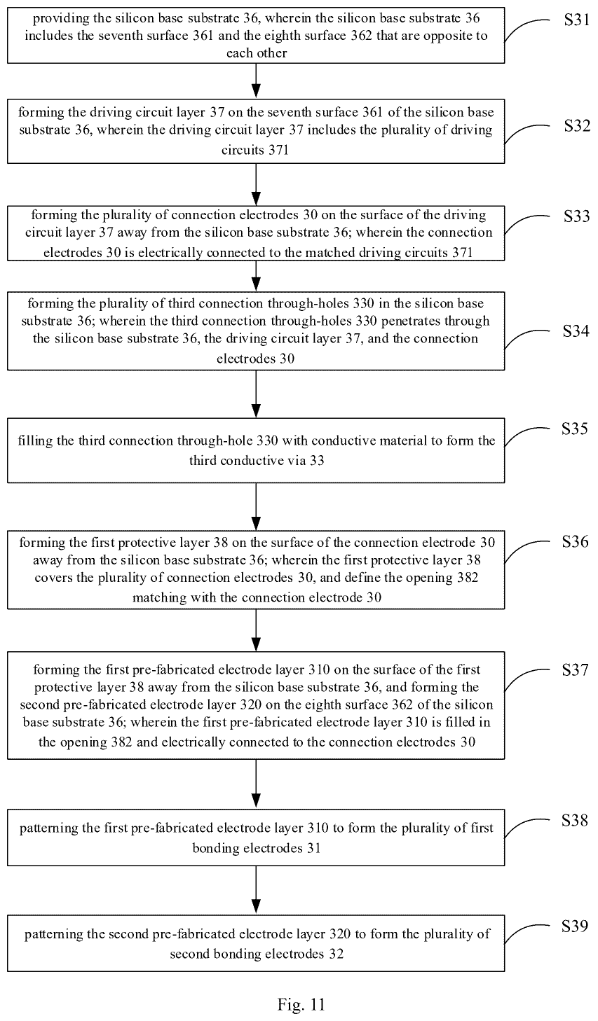

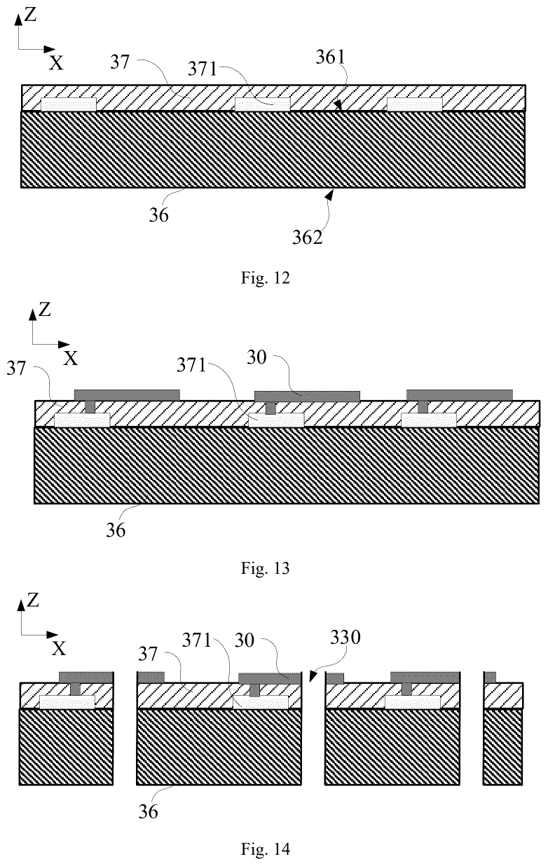

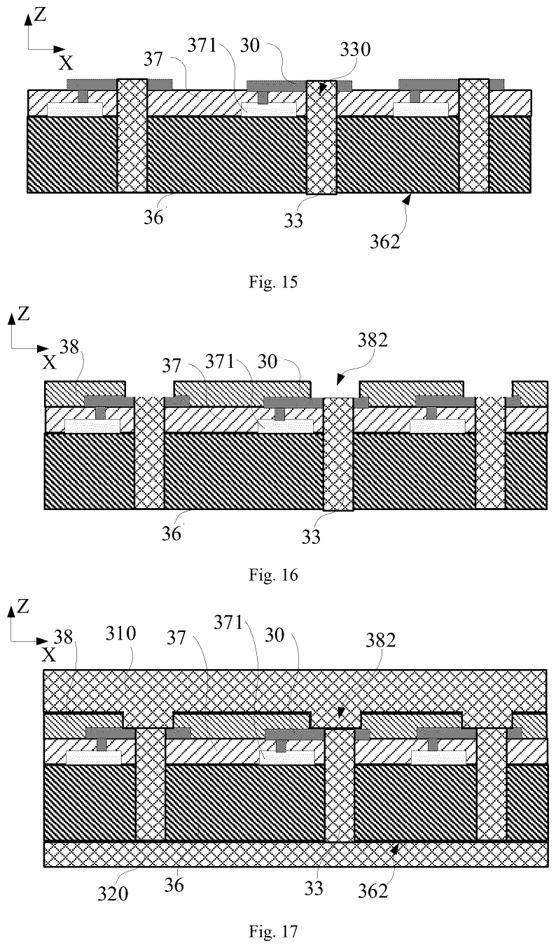

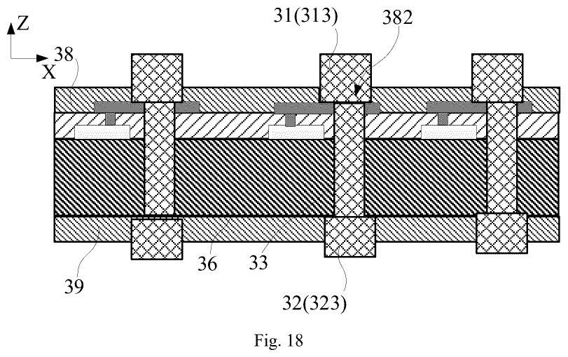

As illustrated in FIG. 11 to FIG. 18, FIG. 11 is a specific schematic flowchart of the operation at block S3. FIG. 12 is a schematic structural view corresponding to the operations at blocks S31 and S32 of FIG. 11. FIG. 13 is a schematic structural view corresponding to the operation at block S33 of FIG. 11. FIG. 14 is a schematic structural view corresponding to the operation at block S34 of FIG. 11. FIG. 15 is a schematic structural view corresponding to the operation at block S35 of FIG. 11. FIG. 16 is a schematic structural view corresponding to the operation at block S36 of FIG. 11. FIG. 17 is a schematic structural view corresponding to the operation at block S37 of FIG. 11. FIG. 18 is a schematic structural view corresponding to the operations at blocks S38 and S39 of FIG. 11.

As illustrated in FIG. 11, in a specific implementation process, The operation at block S3 may further specifically include the following operations.

The operation at block S31: providing the silicon base substrate 36, wherein, the silicon base substrate 36 may include the seventh surface 361 and the eighth surface 362 that are opposite to each other.

The operation at block S32: forming the driving circuit layer 37 on the seventh surface 361 of the silicon base substrate 36, wherein the driving circuit layer 37 may include the plurality of driving circuits 371.

In some embodiments, as illustrated in FIG. 12, the silicon base substrate 36 may be a monocrystalline silicon substrate. By fabricating the driving circuit layer 37 on the silicon base substrate 36 and separately preparing the light-emitting units and the silicon-based driving substrate 3, production efficiency may be increased. Moreover, by using the silicon base substrate 36 as an underlayer substrate of the silicon-based driving substrate 3, the advantages of the silicon-based driving substrate 3 may be retained. Meanwhile, by using the glass substrate as the underlayer substrate of the light-emitting units, costs may be saved. The glass substrate has better stability, is less prone to deformation due to temperature, and is beneficial to maintaining the stability and electrical performance of the light-emitting devices. Additionally, the glass substrate has better light transmittance, which is beneficial to increasing a brightness of the display panel.

The operation at block S33: forming the plurality of connection electrodes 30 on the surface of the driving circuit layer 37 away from the silicon base substrate 36; wherein the connection electrodes 30 may be electrically connected to the matched driving circuits 371.

In some embodiments, as illustrated in FIG. 13, along the first direction X, one end of the connection electrode 30 may be electrically connected to the matched driving circuit 371; and another end of the connection electrode 30 may extend on the surface of the driving circuit layer 37 away from the silicon base substrate 36 and cover the portion of the driving circuit layer 37 where no driving circuit 371 is provided. The plurality of connection electrodes 30 may be arranged in a two-dimensional array on the surface of the driving circuit layer 37.

The operation at block S34: forming the plurality of third connection through-holes 330 in the silicon base substrate 36; wherein the third connection through-holes 330 may penetrate through the silicon base substrate 36, the driving circuit layer 37, and the connection electrodes 30.

As illustrated in FIG. 14, in a specific implementation process, the mask etching method may be adopted to etch the connection electrodes 30, the driving circuit layer 37, and the silicon base substrate 36 in sequence, so as to form the third connection through-holes 330 penetrating through the connection electrodes 30, the driving circuit layer 37, and the silicon base substrate 36. Specifically, the specific etching method may be selected according to the material of the etched film layer. For example, wet etching may be adopted to etch the connection electrodes 30. The plurality of third connection through-holes 330 may be arranged in the two-dimensional array, and may be spaced apart from the driving circuits 371 in the first direction X, so as to avoid damaging the driving circuits 371.

The operation at block S35: filling the third connection through-hole 330 with conductive material to form the third conductive via 33.

In some embodiments, as illustrated in FIG. 15, one end of the third conductive via 33 along the stacking direction Z may flush with the side surface of the connection electrode 30 away from the silicon base substrate 36, and may be in contact with the connection electrode 30, so as to electrically connect the third conductive via 33 with the driving circuit 371. Another end of the third conductive via 33 along the stacking direction Z may flush with the eighth surface 362 of the silicon base substrate 36. The drive signal of the driving circuit 371 may be transmitted to the third conductive via 33 through the connection electrode 30.

The operation at block S36: forming the first protective layer 38 on the surface of the connection electrode 30 away from the silicon base substrate 36; wherein the first protective layer 38 may cover the plurality of connection electrodes 30, and define the opening 382 matching with the connection electrode 30.

Specifically, as illustrated in FIG. 16, the inorganic insulating material may be deposited on the side of the driving circuit layer 37 away from the silicon base substrate 36 to form the first protective layer 38, and the first protective layer 38 may be enabled to cover the surface of the connection electrodes 30 and to cover the surface of the driving circuit layer 37 not covered by the connection electrodes 30. Specifically, the inorganic insulating material may be the silicon dioxide, the silicon nitride, or the silicon oxynitride.

The mask etching method may be adopted to etch the first protective layer 38 at locations matching with the connection electrode 30 and the third conductive via 33 to define the opening 382, so as to expose the third conductive via 33 and a portion of the connection electrodes 30.

The operation at block S37: forming a first pre-fabricated electrode layer 310 on the surface of the first protective layer 38 away from the silicon base substrate 36, and forming a second pre-fabricated electrode layer 320 on the eighth surface 362 of the silicon base substrate 36; wherein the first pre-fabricated electrode layer 310 may be filled in the opening 382 and electrically connected to the connection electrodes 30.

In some embodiments, as illustrated in FIG. 17, the conductive material may be deposited on the surface of the first protective layer 38 away from the silicon base substrate 36 and in the opening 382 by the chemical vapor deposition (CVD) or the physical vapor deposition (PVD) to form the first pre-fabricated electrode layer 310, so that the first pre-fabricated electrode layer 310 may be electrically connected to the connection electrodes 30 and the third conductive via 33. The conductive material may be deposited on the eighth surface 362 of the silicon base substrate 36 to form the second pre-fabricated electrode layer 320, so that the second pre-fabricated electrode layer 320 may be electrically connected to the third conductive via 33.

The operation at block S38: patterning the first pre-fabricated electrode layer 310 to form the plurality of first bonding electrodes 31.

Specifically, as illustrated in FIG. 18, the first pre-fabricated electrode layer 310 may be patterned by the mask etching method, and a portion of the first pre-fabricated electrode layer 310 matching with the plurality of openings 382 may be retained to form the plurality of first bonding electrodes 31 arranged at intervals. The first bonding electrode 31 may fill the opening 382 and protrude beyond the first protective layer 38 to form the first protruding portion 313.

The operation at block S39: patterning the second pre-fabricated electrode layer 320 to form the plurality of second bonding electrodes 32.

Specifically, as illustrated in FIG. 18, The second pre-fabricated electrode layer 320 may be patterned by the mask etching method, and a portion of the second pre-fabricated electrode layer 320 matching with the plurality of third conductive vias 33 may be retained to form the plurality of second bonding electrodes 32 arranged at intervals.

After the operation of forming the plurality of second bonding electrodes 32, the method may further include: forming the second protective layer 39 on the eighth surface 362 of the silicon base substrate 36.

Specifically, as illustrated in FIG. 18, the inorganic insulating material is deposited on the eighth surface 362 of the silicon base substrate 36 to form the first protective layer 38, and the second bonding electrodes 32 protrude from the second protective layer 39 to form second protruding portions 323.

The operation at block S4: bonding the fifth surface 34 of the silicon-based driving substrate 3 to the second surface 112 of the first glass substrate 11, and bonding the sixth surface 35 of the silicon-based driving substrate 3 to the fourth surface 212 of the second glass substrate 21.

In some embodiments, as illustrated in FIG. 1, an end of each third anode-electrode conductive via 331 proximate to the first anode-electrode bonding electrode 311 may be electrically connected to the matched first anode-electrode conductive via 1131, and another end of the each third anode-electrode conductive via 331 may be electrically connected to a matched second anode-electrode conductive via 2131, so that the driving circuit may synchronously transmit the anode drive signals to the matched first anode-electrode conductive via 1131 and the matched second anode-electrode conductive via 2131 through the third anode-electrode conductive via 331.

An end of each third cathode-electrode conductive via 332 proximate to the first cathode-electrode bonding electrode 312 may be electrically connected to the matched first cathode-electrode conductive via 1132, and another end of the each third cathode-electrode conductive via 332 may be electrically connected to a matched second cathode-electrode conductive via 2132, so that the driving circuit may synchronously transmit the cathode drive signals to the matched first cathode-electrode conductive via 1132 and the matched second cathode-electrode conductive via 2132 through the third cathode-electrode conductive via 332.

In a specific implementation process, the operation at block S4 may further specifically include the following operations.

Operation S41: aligning and bonding the first bonding portion 13 and the first bonding electrode 31 matching with each other; and aligning and bonding the second bonding portion 23 and the second bonding electrode 32 matching with each other.

Specifically, as illustrated in FIG. 1, aligning and bonding the first anode-electrode bonding portion 131 with the matched first anode-electrode bonding electrode 311, to electrically connect the first anode-electrode conductive via 1131 with the matched third anode-electrode conductive via 331. Aligning and bonding the first cathode-electrode bonding portion 132 with the matched first cathode-electrode bonding electrode 312, to electrically connect the first cathode-electrode conductive via 1132 with the matched third cathode-electrode conductive via 332.

Aligning and bonding the second anode-electrode bonding portion 231 with the matched second anode-electrode bonding electrode 321, to electrically connect the second anode-electrode conductive via 2131 with the matched third anode-electrode conductive via 331. Aligning and bonding the second cathode-electrode bonding portion with the matched second cathode-electrode bonding electrode 322, to electrically connect the second cathode-electrode conductive via 2132 with the matched third cathode-electrode conductive via 332.

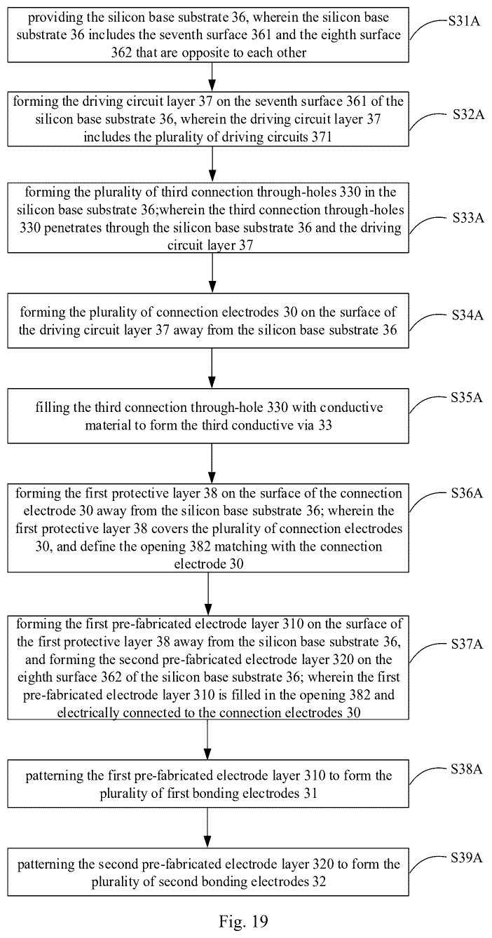

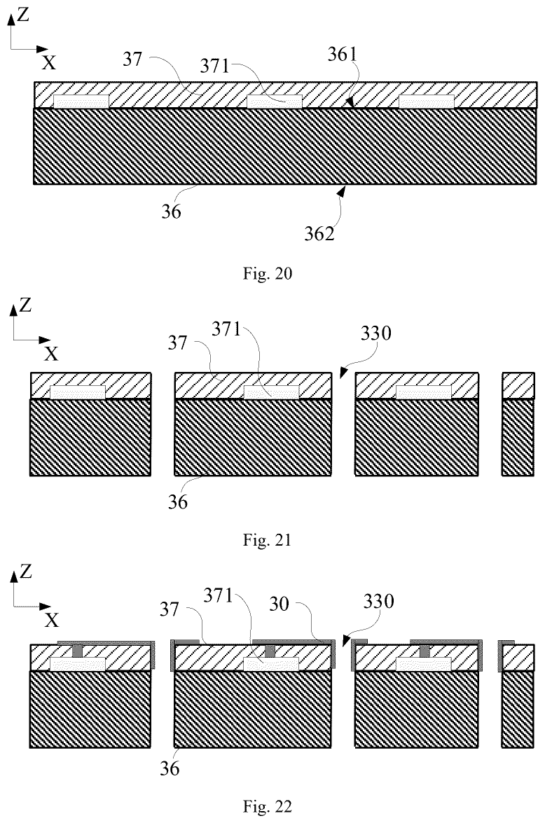

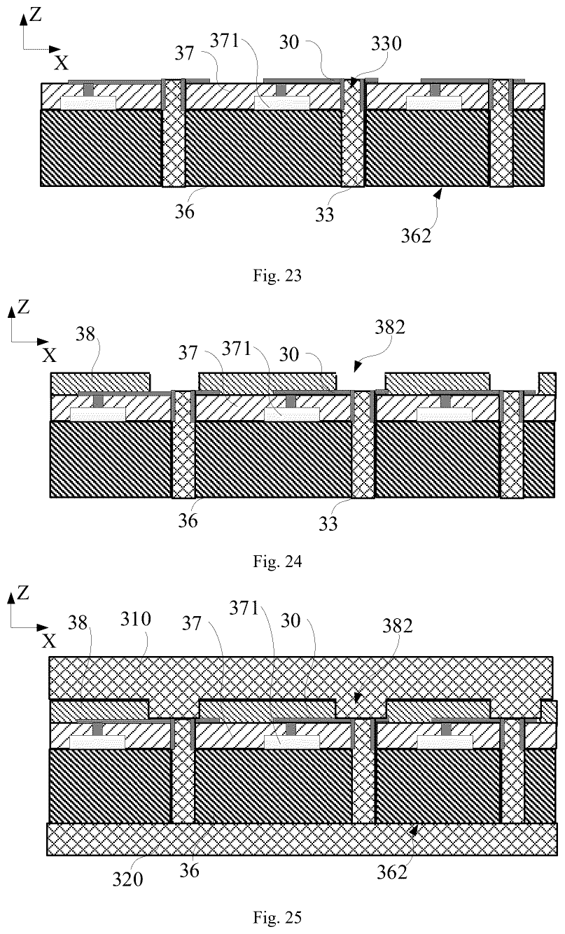

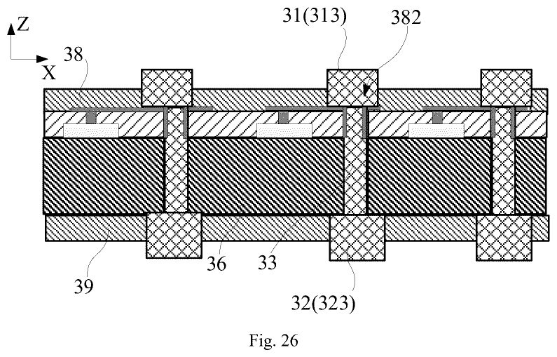

As illustrated in FIG. 19 to FIG. 26, FIG. 19 is a schematic flowchart of a fourth embodiment of an operation at block S3 of the preparation method of a display panel according to the present disclosure. FIG. 20 is a schematic structural view corresponding to the operations at blocks S31A and S32A of FIG. 19. FIG. 21 is a schematic structural view corresponding to the operation at block S33A of FIG. 19. FIG. 22 is a schematic structural view corresponding to the operation at block S34A of FIG. 19. FIG. 23 is a schematic structural view corresponding to the operation at block S35A of FIG. 19. FIG. 24 is a schematic structural view corresponding to the operation at block S36A of FIG. 19. FIG. 25 is a schematic structural view corresponding to the operation at block S37A of FIG. 19. FIG. 26 is a schematic structural view corresponding to the operations at blocks S38A and S39A of FIG. 19. The preparation method of the display panel provided in the fourth embodiment of the present disclosure is basically the same as that provided in the third embodiment of the present disclosure. The difference may lie in the following that: in the fourth embodiment, the plurality of third connection through-holes 330 may be formed first, and then the plurality of connection electrodes 30 may be formed, thus the connection electrodes 30 may be enabled to extend into the third connection through-holes 330. In this way, a contact area between the connection electrode 30 and the third conductive via 33 may be increased, the risk of connection failure between the connection electrode 30 and the third conductive via 33 may be reduced, thereby reducing the conductive resistance, and effectively enhancing the conductive effect.

In the specific implementation process, the operation at block S3 may specifically include the operations at blocks as illustrated in FIG. 19.

The operation at block S31A: providing the silicon base substrate 36, wherein, the silicon base substrate 36 may include the seventh surface 361 and the eighth surface 362 that are opposite to each other.

The operation at block S32A: forming the driving circuit layer 37 on the seventh surface 361 of the silicon base substrate 36, wherein the driving circuit layer 37 may include the plurality of driving circuits 371.

The operation at block S33A: forming the plurality of third connection through-holes 330 in the silicon base substrate 36; wherein the third connection through-holes 330 may penetrate through the silicon base substrate 36 and the driving circuit layer 37.

Specifically, as illustrated in FIG. 21, in a specific implementation process, the mask etching method may be adopted to etch the driving circuit layer 37 and the silicon base substrate 36 in sequence, so as to form the third connection through-holes 330 penetrating through the driving circuit layer 37 and the silicon base substrate 36. Specifically, the specific etching method may be selected according to the material of the etched film layer. For example, dry etching may be adopted to etch the connection electrodes 37.

The operation at block S34A: forming the plurality of connection electrodes 30 on the surface of the driving circuit layer 37 away from the silicon base substrate 36.

Specifically, as illustrated in FIG. 22, along the first direction X, one end of the connection electrode 30 may be electrically connected to the matched driving circuit 371; and another end of the connection electrode 30 may extend on the surface of the driving circuit layer 37 away from the silicon base substrate 36 and cover the portion of the driving circuit layer 37 where no driving circuit 371 is provided. The portion of the connection electrode 30 matching with the third connection through-hole 330 may extend into the third connection through-hole 330, and may cover a portion of an inner wall of the third connection through-hole 330.

The operation at block S35A: filling the third connection through-hole 330 with conductive material to form the third conductive via 33.

Specifically, as illustrated in FIG. 23, the third conductive via 33 may cover the portion of the connection electrodes 30 located within the third connection through-hole 330, so as to achieve the electrical connection between the third conductive via 33 and the driving circuit 371, the contact area between the connection electrode 30 and the third conductive via 33 may be further increased. One end of the third conductive via 33 along the stacking direction Z may flush with the side surface of the connection electrode 30 away from the silicon base substrate 36, and the another end of the third conductive via 33 may flush with the eighth surface 362 of the silicon base substrate 36. The drive signal of the driving circuit 371 may be transmitted to the third conductive via 33 through the connection electrode 30.

The operation at block S36A: forming the first protective layer 38 on the surface of the connection electrode 30 away from the silicon base substrate 36; wherein the first protective layer 38 may cover the plurality of connection electrodes 30, and define the opening 382 matching with the connection electrode 30.

The operation at block S37A: forming the first pre-fabricated electrode layer 310 on the surface of the first protective layer 38 away from the silicon base substrate 36, and forming the second pre-fabricated electrode layer 320 on the eighth surface 362 of the silicon base substrate 36; wherein the first pre-fabricated electrode layer 310 may be filled in the opening 382 and electrically connected to the connection electrodes 30.

The operation at block S38A: patterning the first pre-fabricated electrode layer 310 to form the plurality of first bonding electrodes 31.

The operation at block S39A: patterning the second pre-fabricated electrode layer 320 to form the plurality of second bonding electrodes 32.

After the operation of forming the plurality of second bonding electrodes 32, the method may further include: forming the second protective layer 39 on the eighth surface 362 of the silicon base substrate 36.

The present disclosure provides the preparation method of the display panel. The preparation method may specifically include: first, providing a first display substrate 1, wherein the first display substrate 1 may include the first glass substrate 11 and the plurality of first light-emitting units 12; next, providing the second display substrate 2, wherein the second display substrate 2 may include the second glass substrate 21 and the plurality of second light-emitting units 22; next, providing the silicon-based driving substrate 3; finally, bonding the fifth surface 34 of the silicon-based driving substrate 3 to the second surface 112 of the first glass substrate 11, and bonding the sixth surface 35 of the silicon-based driving substrate 3 to the fourth surface 212 of the second glass substrate 21. This display panel prepared by the preparation method of the display panel may avoid the problem that fabricating the light-emitting units directly on the silicon-based driving substrate 3 causes damage to the pixel driving circuits 371. The double-sided synchronous display may further be achieved.

The above are only implementations of the present disclosure, and do not limit the patent scope of the present disclosure. Any equivalent changes to the structure or processes made by the description and drawings of the present disclosure or directly or indirectly used in other related technical field are included in the protection scope of the present disclosure.

1. A display panel, comprising:
a first display substrate, comprising:
a first glass substrate, comprising a first surface and a second surface that are opposite to each other; wherein the first glass substrate comprises a plurality of first conductive vias extending from the first surface to the second surface; the plurality of first conductive vias comprise a plurality of first anode-electrode conductive vias and a plurality of first cathode-electrode conductive vias; and
a plurality of first light-emitting units, arranged on the first surface of the first glass substrate; wherein each of the plurality of first light-emitting units comprises a first anode electrode, a first organic light-emitting layer, and a first cathode electrode that are stacked in sequence in a direction away from the first glass substrate; the first anode electrode is electrically connected to a matched one of the plurality of first anode-electrode conductive vias; the first cathode electrode is electrically connected to one of the plurality of first cathode-electrode conductive vias;
a second display substrate, comprising:
a second glass substrate, comprising a third surface and a fourth surface that are opposite to each other; wherein the second glass substrate comprises a plurality of second conductive vias extending from the third surface to the fourth surface; the plurality of second conductive vias comprise a plurality of second anode-electrode conductive vias and a plurality of second cathode-electrode conductive vias; and
a plurality of second light-emitting units, arranged on the third surface of the second glass substrate; wherein each of the plurality of second light-emitting units comprises a second anode electrode, a second organic light-emitting layer, and a second cathode electrode that are stacked in sequence in a direction away from the second glass substrate; the second anode electrode is electrically connected to a matched one of the plurality of second anode-electrode conductive vias; the second cathode electrode is electrically connected to one of the plurality of second cathode-electrode conductive vias; and
a silicon-based driving substrate, stacked between the first glass substrate and the second glass substrate; wherein the silicon-based driving substrate comprises a fifth surface and a sixth surface that are opposite to each other; the fifth surface of the silicon-based driving substrate is bonded to the second surface of the first glass substrate; the sixth surface of the silicon-based driving substrate is bonded to the fourth surface of the second glass substrate;
wherein the silicon-based driving substrate comprises a plurality of third conductive vias extending from the fifth surface to the sixth surface; each of the plurality of third conductive vias is electrically connected to a driving circuit of the silicon-based driving substrate; the plurality of third conductive vias comprise a plurality of third anode-electrode conductive vias and a plurality of third cathode-electrode conductive vias; an end of each of the plurality of third anode-electrode conductive vias is electrically connected to matched one of the plurality of first anode-electrode conductive vias, another end of the each of the plurality of third anode-electrode conductive vias is electrically connected to matched one of the plurality of second anode-electrode conductive vias; an end of each of the plurality of third cathode-electrode conductive vias is electrically connected to matched one of the plurality of first cathode-electrode conductive vias, another end of the each of the plurality of third cathode-electrode conductive vias is electrically connected to matched one of the plurality of second cathode-electrode conductive vias.

2. The display panel as claimed in claim 1, wherein
the first display substrate further comprises a plurality of first bonding portions; wherein the plurality of first bonding portions comprise:
a plurality of first anode-electrode bonding portions, wherein each of the plurality of first anode-electrode bonding portions is at least partially arranged within matched one of the plurality of first anode-electrode conductive vias; the each of the plurality of first anode-electrode bonding portions is electrically connected to a matched first anode electrode through the matched one of the plurality of first anode-electrode conductive vias; and
a plurality of first cathode-electrode bonding portions, wherein each of the plurality of first cathode-electrode bonding portions is at least partially arranged within matched one of the plurality of first cathode-electrode conductive vias; the each of the plurality of first cathode-electrode bonding portions is electrically connected to the first cathode electrode through the matched one of the plurality of first cathode-electrode conductive vias;
the second display substrate further comprises a plurality of second bonding portions; wherein the plurality of second bonding portions comprise:
a plurality of second anode-electrode bonding portions, wherein each of the plurality of second anode-electrode bonding portions is at least partially arranged within matched one of the plurality of second anode-electrode conductive vias; the each of the plurality of second anode-electrode bonding portions is electrically connected to a matched second anode electrode through the matched one of the plurality of second anode-electrode conductive vias; and
a plurality of second cathode-electrode bonding portions, wherein each of the plurality of second cathode-electrode bonding portions is at least partially arranged within matched one of the plurality of second cathode-electrode conductive vias; the each of the plurality of second cathode-electrode bonding portions is electrically connected to the second cathode electrode through the matched one of the plurality of second cathode-electrode conductive vias;
the silicon-based driving substrate further comprises:
a plurality of first bonding electrodes, comprising:
a plurality of first anode-electrode bonding electrodes, arranged on the fifth surface of the silicon-based driving substrate; wherein the plurality of first anode-electrode bonding electrodes are aligned and bonded with the plurality of first anode-electrode bonding portions in one-to-one correspondence; and
a plurality of first cathode-electrode bonding electrodes, arranged on the fifth surface of the silicon-based driving substrate; wherein the plurality of first cathode-electrode bonding electrodes are aligned and bonded with the plurality of first cathode-electrode bonding portions in one-to-one correspondence;
a plurality of second bonding electrodes, comprising:
a plurality of second anode-electrode bonding electrodes, arranged on the sixth surface of the silicon-based driving substrate, and electrically connected to matched one of the plurality of first anode-electrode bonding electrodes through one of the plurality of third anode-electrode conductive vias; wherein the plurality of second anode-electrode bonding electrodes are aligned and bonded with the plurality of second anode-electrode bonding portions in one-to-one correspondence; and
a plurality of second cathode-electrode bonding electrodes, arranged on the sixth surface of the silicon-based driving substrate, and electrically connected to matched one of the plurality of first cathode-electrode bonding electrodes through one of the plurality of third cathode-electrode conductive vias; wherein the plurality of second cathode-electrode bonding electrodes are aligned and bonded with the plurality of second cathode-electrode bonding portions in one-to-one correspondence.

3. The display panel as claimed in claim 2, wherein
the first display substrate further comprises:
a first insulating layer, arranged on the second surface of the first glass substrate; wherein the first insulating layer defines a first through-hole; each of the plurality of first bonding portions is embedded in the first through-hole; a surface of the each of the plurality of first bonding portions away from the first glass substrate is lower than a surface of the first insulating layer away from the first glass substrate, defining a first groove portion;
the second display substrate further comprises:
a second insulating layer, arranged on the fourth surface of the second glass substrate; wherein the second insulating layer defines a second through-hole; each of the plurality of second bonding portions is embedded in the second through-hole; a surface of the each of the plurality of second bonding portions away from the second glass substrate is lower than a surface of the second insulating layer away from the second glass substrate, defining a second groove portion;
the silicon-based driving substrate comprises:
a silicon base substrate, comprising a seventh surface and an eighth surface that are opposite to each other;
a driving circuit layer, arranged on the seventh surface of the silicon base substrate, and comprising the driving circuit;
a first protective layer, covering the driving circuit layer; wherein the first protective layer defines a third through-hole; a portion of each of the plurality of first bonding electrodes is embedded in the third through-hole, another portion of the each of the plurality of first bonding electrodes protrudes beyond the first protective layer, forming a first protruding portion; the first protruding portion is embedded in the first groove portion; and
a second protective layer, arranged on the eighth surface of the silicon base substrate; wherein the second protective layer defines a fourth through-hole; a portion of each of the plurality of second bonding electrodes is embedded in the fourth through-hole, another portion of the each of the plurality of second bonding electrodes protrudes beyond the second protective layer, forming a second protruding portion; the second protruding portion is embedded in the second groove portion.

4. The display panel as claimed in claim 3, wherein
a first conductive via of the plurality of first conductive vias, a third conductive via of the plurality of third conductive vias, and a second conductive via of the plurality of second conductive vias matching with each other are coaxially arranged;
wherein between the first conductive via and the third conductive via matching with each other, a first bonding electrode of the plurality of first bonding electrodes and a first bonding portion of the plurality of first bonding portions are arranged and bonded to each other; between the second conductive via and the third conductive via matching with each other, a second bonding electrode of the plurality of second bonding electrodes and a second bonding portion of the plurality of second bonding portions are arranged and bonded to each other.

5. The display panel as claimed in claim 3, wherein
the first conductive via and the third conductive via matching with each other are arranged in a misaligned manner; the second conductive via and the third conductive via matching with each other are arranged in a misaligned manner;
wherein between the first glass substrate and a third conductive via of the plurality of third conductive vias, a first bonding electrode of the plurality of first bonding electrodes and a first bonding portion of the plurality of first bonding portions are arranged and bonded to each other; between the second glass substrate and a third conductive via of the plurality of third conductive vias, a second bonding electrode of the plurality of second bonding electrodes and a second bonding portion of the plurality of second bonding portions are arranged and bonded to each other.

6. The display panel as claimed in claim 5, wherein
a portion of the first bonding portion is arranged within the first conductive via, and another portion of the first bonding portion is arranged outside the first conductive via, the another portion of the first bonding portion covers a portion of the second surface, the first protruding portion is bonded to the another portion of the first bonding portion.

7. The display panel as claimed in claim 6, wherein
the another portion of the first bonding portion extends from the first conductive via along a first direction perpendicular to a stacking direction of the display panel.

8. The display panel as claimed in claim 5, wherein
a portion of the second bonding portion is arranged within the second conductive via, and another portion of the second bonding portion is arranged outside the second conductive via, the another portion of the second bonding portion covers a portion of the fourth surface, the second protruding portion is bonded to the another portion of the second bonding portion.

9. The display panel as claimed in claim 8, wherein
the another portion of the second bonding portion extends from the second conductive via along a first direction perpendicular to a stacking direction of the display panel.

10. The display panel as claimed in claim 5, wherein
a first conductive via of the plurality of first conductive vias and a second conductive via of the plurality of second conductive vias matching with each other are coaxially arranged.

11. A preparation method of a display panel, comprising:
providing a first display substrate; wherein the first display substrate comprises:
a first glass substrate, comprising a first surface and a second surface that are opposite to each other; wherein the first glass substrate comprises a plurality of first conductive vias extending from the first surface to the second surface; the plurality of first conductive vias comprise a plurality of first anode-electrode conductive vias and a plurality of first cathode-electrode conductive vias; and
a plurality of first light-emitting units, arranged on the first surface of the first glass substrate;
wherein each of the plurality of first light-emitting units comprises a first anode electrode, a first organic light-emitting layer, and a first cathode electrode that are stacked in sequence in a direction away from the first glass substrate; the first anode electrode is electrically connected to a matched one of the plurality of first anode-electrode conductive vias; the first cathode electrode is electrically connected to one of the plurality of first cathode-electrode conductive vias;
providing a second display substrate; wherein the second display substrate comprises:
a second glass substrate, comprising a third surface and a fourth surface that are opposite to each other; wherein the second glass substrate comprises a plurality of second conductive vias extending from the third surface to the fourth surface; the plurality of second conductive vias comprise a plurality of second anode-electrode conductive vias and a plurality of second cathode-electrode conductive vias; and
a plurality of second light-emitting units, arranged on the third surface of the second glass substrate; wherein each of the plurality of second light-emitting units comprises a second anode electrode, a second organic light-emitting layer, and a second cathode electrode that are stacked in sequence in a direction away from the second glass substrate; the second anode electrode is electrically connected to a matched one of the plurality of second anode-electrode conductive vias; the second cathode electrode is electrically connected to one of the plurality of second cathode-electrode conductive vias;
providing a silicon-based driving substrate; wherein the silicon-based driving substrate comprises a fifth surface and a sixth surface that are opposite to each other; the silicon-based driving substrate comprises a plurality of third conductive vias extending from the fifth surface to the sixth surface; each of the plurality of third conductive vias is electrically connected to a driving circuit of the silicon-based driving substrate; the plurality of third conductive vias comprise a plurality of third anode-electrode conductive vias and a plurality of third cathode-electrode conductive vias; and
bonding the fifth surface of the silicon-based driving substrate to the second surface of the first glass substrate, and bonding the sixth surface of the silicon-based driving substrate to the fourth surface of the second glass substrate; wherein an end of each third anode-electrode conductive via of the plurality of third anode-electrode conductive vias is electrically connected to a matched first anode-electrode conductive via of the plurality of first anode-electrode conductive vias, another end of the each third anode-electrode conductive via is electrically connected to a matched second anode-electrode conductive via of the plurality of second anode-electrode conductive vias; an end of each third cathode-electrode conductive via of the plurality of third cathode-electrode conductive vias is electrically connected to a matched first cathode-electrode conductive via of the plurality of first cathode-electrode conductive vias, another end of the each third cathode-electrode conductive via is electrically connected to a matched second cathode-electrode conductive via of the plurality of second cathode-electrode conductive vias.

12. The preparation method of the display panel as claimed in claim 11, wherein
the providing the first display substrate further comprises: forming a plurality of first bonding portions on the second surface of the first glass substrate; wherein the plurality of first bonding portions comprise a plurality of first anode-electrode bonding portions and a plurality of first cathode-electrode bonding portions; each of the plurality of first bonding portions is electrically connected to a matched first conductive via of the plurality of first conductive vias;
the providing the second display substrate further comprises: forming a plurality of second bonding portions on the fourth surface of the second glass substrate; wherein the plurality of second bonding portions comprise a plurality of second anode-electrode bonding portions and a plurality of second cathode-electrode bonding portions; each of the plurality of second bonding portions is electrically connected to a matched second conductive via of the plurality of second conductive vias;
the providing the silicon-based driving substrate comprises: forming a plurality of first bonding electrodes on the fifth surface of the silicon-based driving substrate, and forming a plurality of second bonding electrodes on the sixth surface of the silicon-based driving substrate; wherein the plurality of first bonding electrodes comprise a plurality of first anode-electrode bonding electrodes and a plurality of first cathode-electrode bonding electrodes; wherein the plurality of second bonding electrodes comprise a plurality of second anode-electrode bonding electrodes and a plurality of second cathode-electrode bonding electrodes; each of the plurality of first bonding electrodes is electrically connected to a matched third conductive via of the plurality of third conductive vias, and each of the plurality of second bonding electrodes is electrically connected to a matched third conductive via of the plurality of third conductive vias;
the bonding the fifth surface of the silicon-based driving substrate to the second surface of the first glass substrate, and bonding the sixth surface of the silicon-based driving substrate to the fourth surface of the second glass substrate comprises: aligning and bonding a first bonding portion of the plurality of first bonding portions and a first bonding electrode of the plurality of first bonding electrodes matching with each other, and aligning and bonding a second bonding portion of the plurality of second bonding portions and a second bonding electrode of the plurality of second bonding electrodes matching with each other.

13. The preparation method of the display panel as claimed in claim 12, wherein
the providing the silicon-based driving substrate comprises:
providing a silicon base substrate; wherein the silicon base substrate comprises a seventh surface and an eighth surface that are opposite to each other;
forming a driving circuit layer on the seventh surface of the silicon base substrate; wherein the driving circuit layer comprises a plurality of driving circuits;
forming a plurality of connection electrodes on a surface of the driving circuit layer away from the silicon base substrate; wherein each of the plurality of connection electrodes is electrically connected to a matched driving circuit of the plurality of driving circuits;
forming a plurality of third connection through-holes in the silicon base substrate; wherein each of the plurality of third connection through-holes penetrates through the silicon base substrate, the driving circuit layer, and one of the plurality of connection electrodes;
filling each of the plurality of third connection through-holes with conductive material, to form one of the plurality of third connection through-holes;
forming a first protective layer on a surface of the each of the plurality of connection electrodes away from the silicon base substrate; wherein the first protective layer covers the plurality of connection electrodes, and defines an opening for the each of the plurality of connection electrodes;
forming a first pre-fabricated electrode layer on a surface of the first protective layer away from the silicon base substrate, and forming a second pre-fabricated electrode layer on the eighth surface of the silicon base substrate; wherein the first pre-fabricated electrode layer is filled within the opening, and is electrically connected to the each of the plurality of connection electrodes;
patterning the first pre-fabricated electrode layer to form a plurality of first bonding electrodes; and
patterning the second pre-fabricated electrode layer to form a plurality of second bonding electrodes.

14. The preparation method of the display panel as claimed in claim 12, wherein
the providing the silicon-based driving substrate comprises:
providing a silicon base substrate; wherein the silicon base substrate comprises a seventh surface and an eighth surface that are opposite to each other;
forming a driving circuit layer on the seventh surface of the silicon base substrate; wherein the driving circuit layer comprises a plurality of driving circuits;
forming a plurality of third connection through-holes in the silicon base substrate; wherein each of the plurality of third connection through-holes penetrates through the silicon base substrate and the driving circuit layer;
forming a plurality of connection electrodes on a surface of the driving circuit layer away from the silicon base substrate; wherein each of the plurality of connection electrodes is electrically connected to a matched driving circuit of the plurality of driving circuits, and a portion of the each of the plurality of connection electrodes extends to an inner wall of a third connection through-hole of the plurality of third connection through-holes;
filling each of the plurality of third connection through-holes with conductive material, to form one of the plurality of third connection through-holes;
forming a first protective layer on a surface of the each of the plurality of connection electrodes away from the silicon base substrate; wherein the first protective layer covers the plurality of connection electrodes, and defines an opening for the each of the plurality of connection electrodes;
forming a first pre-fabricated electrode layer on a surface of the first protective layer away from the silicon base substrate, and forming a second pre-fabricated electrode layer on the eighth surface of the silicon base substrate; wherein the first pre-fabricated electrode layer is filled within the opening, and is electrically connected to the each of the plurality of connection electrodes;
patterning the first pre-fabricated electrode layer to form a plurality of first bonding electrodes; and
patterning the second pre-fabricated electrode layer to form a plurality of second bonding electrodes.
